(19) United States
(12) Patent Application Publication
(10) Pub. No.: US 2026/0107556 A1
(43) Pub. Date: Apr. 16, 2026

(54) SEMICONDUCTOR DEVICE

(71) Applicant: SAMSUNG ELECTRONICS CO., LTD., Suwon-si (KR)

(72) Inventors: Bok Young LEE, Suwon-si (KR); Dong Woo Kim, Suwon-si (KR); Chul Sung Kim, Suwon-si (KR); Hyun Woo Kim, Suwon-si (KR); Dong Hyun Roh, Suwon-si (KR); Suek Woo Choi, Suwon-si (KR)

(73) Assignee: SAMSUNG ELECTRONICS CO., LTD., Suwon-si (KR)

(21) Appl. No.: 19/209,265

(22) Filed: May 15, 2025

(30) Foreign Application Priority Data
Oct. 14, 2024 (KR) 10-2024-0139479

(51) Int. Cl. H10D 84/01; H10D 84/83

(52) U.S. Cl. CPC H10D 84/0153; H10D 84/0128; H10D 84/013; H10D 84/0149; H10D 84/832

(57) ABSTRACT

A semiconductor device is provided. The semiconductor device includes an active pattern extending along a first horizontal direction on an upper surface of a substrate, first nanosheets spaced apart from each other along a vertical direction on the active pattern, a first gate electrode extending along a second horizontal direction on the active pattern, an active cut spaced apart from the first gate electrode in the first horizontal direction, a bottom surface of the active cut formed lower than a bottom surface of the gate electrode, a source/drain region between the first gate electrode and the active cut on the active pattern, and a source/drain contact on an upper surface of the source/drain region. The source/drain contact is electrically connected to the source/drain region, and an uppermost surface of the source/drain contact is formed lower than an upper surface of the active cut.

### CROSS-REFERENCE TO RELATED APPLICATION

This application claims priority from Korean Patent Application No. 10-2024-0139479, filed on Oct. 14, 2024, in the Korean Intellectual Property Office, the disclosure of which is incorporated by reference herein in its entirety.

### BACKGROUND

### Field

The present disclosure relates to a semiconductor device. More particularly, the present disclosure relates to a semiconductor device including a Multi-Bridge Channel Field Effect Transistor (MBCFET™).

### Related Art

Density of integrated circuit devices may be increased by employing multi-channel transistors in which fins or nanowires (or nanosheets) are formed on a substrate to provide channels, and gates are formed on the channels.

Because multi-channel transistors utilize a three-dimensional channel, they are easy to scale. Additionally, the current control capability may be improved without increasing the gate length of the multi-channel transistor. Furthermore, a short channel effect (SCE), in which the potential of the channel region is influenced by the drain voltage, may be effectively suppressed.

### SUMMARY

One or more example embodiments provide a semiconductor device that prevents residuals of the active cut from remaining on the source/drain contact and the gate contact, thereby improving the electrical reliability of each of the source/drain contact and the gate contact.

The present disclosure is not limited to the aspects set forth herein, and another aspect which is not mentioned may be clearly understood by those skilled in the art from the description below.

According to an aspect of an example embodiment, a semiconductor device includes: a substrate; an active pattern extending along a first horizontal direction on an upper surface of the substrate; a first plurality of nanosheets spaced apart from each other along a vertical direction on the active pattern; a first gate electrode extending along a second horizontal direction different from the first horizontal direction on the active pattern, wherein the first gate electrode surrounds the first plurality of nanosheets; an active cut spaced apart from the first gate electrode in the first horizontal direction, wherein a bottom surface of the active cut is provided between a bottom surface of the substrate and a bottom surface of the first gate electrode; a source/drain region provided between the first gate electrode and the active cut on the active pattern; and a source/drain contact provided on an upper surface of the source/drain region, wherein the source/drain contact is electrically connected to the source/drain region, and an uppermost surface of the source/drain contact is provided between the bottom surface of the substrate and an upper surface of the active cut.

According to another aspect of an example embodiment, a semiconductor device including: a substrate; an active pattern extending along a first horizontal direction on an upper surface of the substrate; a first gate electrode extending along a second horizontal direction different from the first horizontal direction on the active pattern; a second gate electrode extending along the second horizontal direction on the active pattern, wherein the second gate electrode is spaced apart from the first gate electrode along the first horizontal direction; an active cut extending along the second horizontal direction between the first gate electrode and the second gate electrode, wherein the active cut is spaced apart from each of the first gate electrode and the second gate electrode along the first horizontal direction; a first source/drain region provided between the first gate electrode and the active cut on the active pattern; a first source/drain contact provided on an upper surface of the first source/drain region, wherein the first source/drain contact is electrically connected to the first source/drain region; and a contact via in contact with an upper surface of the first source/drain contact, wherein the contact via is electrically connected to the first source/drain contact, and an upper surface of the contact via is coplanar with an upper surface of the active cut.

According to another aspect of an example embodiment, a semiconductor device includes: a substrate; an active pattern extending along a first horizontal direction on an upper surface of the substrate; a first plurality of nanosheets spaced apart from each other along a vertical direction on the active pattern; a second plurality of nanosheets spaced apart from each other along the vertical direction on the active pattern, and spaced apart from the first plurality of nanosheets along the first horizontal direction; a third plurality of nanosheets spaced apart from each other along the vertical direction on the active pattern, wherein the third plurality of nanosheets are provided between the first and second plurality of nanosheets, and the third plurality of nanosheets are spaced apart from each of the first and second plurality of nanosheets along the first horizontal direction; a first gate electrode extending along a second horizontal direction different from the first horizontal direction on the active pattern, wherein the first gate electrode surrounds the first plurality of nanosheets; a second gate electrode extending along the second horizontal direction on the active pattern, wherein the second gate electrode is spaced apart from the first gate electrode along the first horizontal direction, and the second gate electrode surrounds the second plurality of nanosheets; a third gate electrode extending along the second horizontal direction on the active pattern, wherein the third gate electrode is provided between the first and second gate electrodes, the third gate electrode is spaced apart from each of the first and second gate electrodes along the first horizontal direction, and the third gate electrode surrounds the third plurality of nanosheets; an active cut extending along the second horizontal direction between the first and second gate electrodes, wherein the active cut penetrates the third plurality of nanosheets and the third gate electrode along the vertical direction; a source/drain region provided between the first gate electrode and the active cut on the active pattern; a source/drain contact provided on an upper surface of the source/drain region, wherein the source/drain contact is electrically connected to the source/drain region, and an uppermost surface of the source/drain contact is provided between a bottom surface of the substrate and an upper surface of the active cut; a contact via in contact with an upper surface of the source/drain contact, wherein the contact via is electrically connected to the source/drain contact, and an upper surface of the contact via is coplanar with the upper surface of the active cut; and a gate contact in contact with an upper surface of the second gate electrode, wherein the gate contact is electrically connected to the second gate electrode, and an upper surface of the gate contact is coplanar with the upper surface of the active cut.

### BRIEF DESCRIPTION OF DRAWINGS

The above and other aspects and features will be more apparent from the following description of example embodiments with reference to the attached drawings, in which:

FIG. 1 is a layout diagram for explaining a semiconductor device according to some example embodiments;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIGS. 5 to 32 are intermediate stage diagrams for explaining a fabrication method of a semiconductor device according to some example embodiments;

FIGS. 33 and 34 are intermediate stage diagrams for explaining a fabrication method of a semiconductor device according to some example embodiments;

FIG. 35 is a cross-sectional view for explaining a semiconductor device according to some example embodiments;

FIGS. 36 to 38 are cross-sectional diagrams for explaining a semiconductor device according to some example embodiments;

FIGS. 39 to 43 are intermediate stage diagrams for explaining a fabrication method of a semiconductor device according to some example embodiments;

FIG. 44 is an intermediate stage diagram for explaining a fabrication method of a semiconductor device according to some example embodiments; and

FIG. 45 is a cross-sectional view for explaining a semiconductor device according to some example embodiments.

### DETAILED DESCRIPTION

Example embodiments will now be described with reference to the accompanying drawings. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation. In the following diagrams, a semiconductor device is described as including, by way of example, a transistor a Multi-Bridge Channel Field Effect Transistor (MBCFET™) that includes nanosheets, but example embodiments are not limited thereto. In some example embodiments, the semiconductor device may include a fin-shaped transistor (FinFET) having a fin-shaped patterned channel region, a tunneling transistor (tunneling FET), or a three-dimensional (3D) transistor. Additionally, the semiconductor device according to some example embodiments may include bipolar junction transistors or laterally-diffused metal-oxide-semiconductor (LDMOS) transistors, among others.

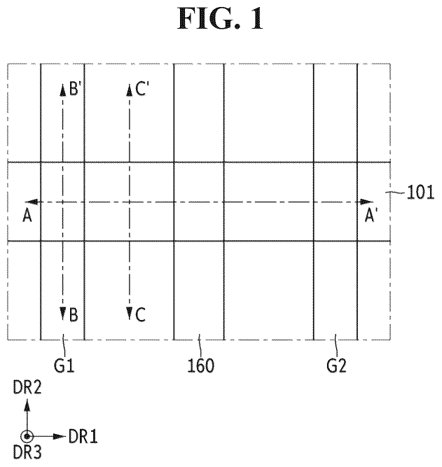

Hereinafter, the semiconductor device according to some example embodiments will be described with reference to FIGS. 1 to 4.

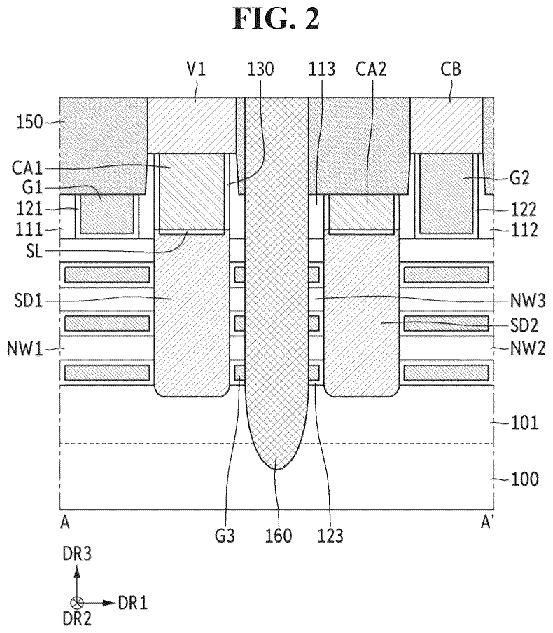

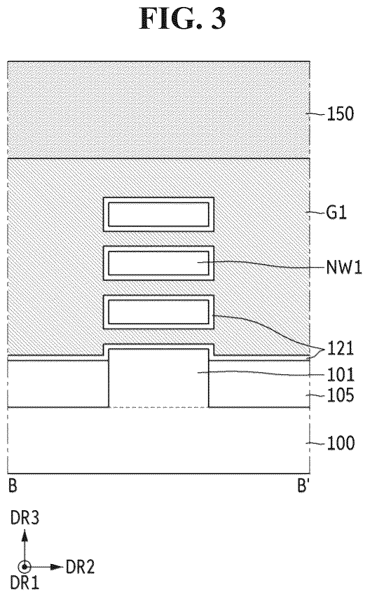

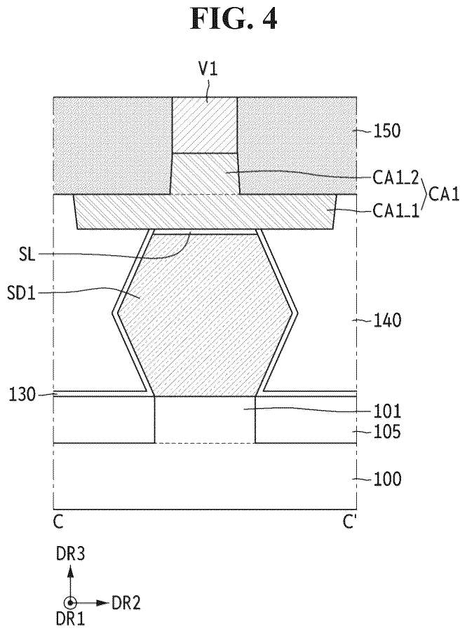

FIG. 1 is a layout diagram for explaining a semiconductor device according to some example embodiments. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1.

Referring to FIGS. 1 to 4, the semiconductor device according to some example embodiments includes a substrate 100, an active pattern 101, a field insulating layer 105, first to third plurality of nanosheets NW1, NW2, NW3, first to third gate electrodes G1, G2, G3, first to third gate spacers 111, 112, 113, first and second source/drain regions SD1, SD2, an etching stop layer 130, a first interlayer insulating layer 140, a second interlayer insulating layer 150, first and second source/drain contacts CA1, CA2, a gate contact CB, a contact via V1, and an active cut 160.

The substrate 100 may be a silicon substrate or silicon-on-insulator (SOI) substrate. Alternatively, the substrate 100 may include silicon germanium, silicon germanium on insulator (SGOI), indium antimonide, lead tellurium compounds, indium arsenide, indium phosphide, gallium arsenide, or gallium antimonide, but example embodiments are not limited thereto.

Hereinafter, each of the first horizontal direction DR1 and the second horizontal direction DR2 may be a direction parallel to the upper surface of the substrate 100. The second horizontal direction DR2 may be parallel to the upper surface of the substrate 100 and may cross the first horizontal direction DR1. The vertical direction DR3 may be a direction perpendicular to each of the first horizontal direction DR1 and the second horizontal direction DR2. In this regard, the vertical direction DR3 may be perpendicular to the upper surface of the substrate 100.

The active pattern 101 may extend in the first horizontal direction DR1 on the upper surface of the substrate 100. The active pattern 101 may protrude from the upper surface of the substrate 100 in the vertical direction DR3. For example, the active pattern 101 may be part of the substrate 100, or may include an epitaxial layer grown from the substrate 100. The field insulating layer 105 may be disposed on the upper surface of the substrate 100. The field insulating layer 105 may surround the sidewalls of the active pattern 101. For example, the upper surface of the field insulating layer 105 may protrude in the vertical direction DR3 compared to the upper surface of the active pattern 101. However, example embodiments are not limited thereto. The field insulating layer 105 may include, for example, an oxide layer, a nitride layer, an oxynitride layer, or a combination thereof.

Each of the first to third plurality of nanosheets NW1, NW2, NW3 may be disposed on the active pattern 101. Each of the first to third plurality of nanosheets NW1, NW2, NW3 may include a plurality of nanosheets stacked and spaced apart from each other in the vertical direction DR3 on the active pattern 101. The third plurality of nanosheets NW3 may be spaced apart from the first plurality of nanosheets NW1 in the first horizontal direction DR1. The second plurality of nanosheets NW2 may be spaced apart from the third plurality of nanosheets NW3 in the first horizontal direction DR1. In this regard, the third plurality of nanosheets NW3 may be disposed between the first plurality of nanosheets NW1 and the second plurality of nanosheets NW2.

In FIGS. 2 and 3, each of the first to third plurality of nanosheets NW1, NW2, NW3 is shown as including three nanosheets stacked and spaced apart from each other in the vertical direction DR3, but this is for convenience of explanation only, and example embodiments are not limited thereto. In some example embodiments, each of the first to third plurality of nanosheets NW1, NW2, NW3 may include four or more nanosheets stacked and spaced apart from each other in the vertical direction DR3. For example, each of the first to third plurality of nanosheets NW1, NW2, NW3 may include silicon (Si). However, example embodiments are not limited thereto. In some example embodiments, each of the first to third plurality of nanosheets NW1, NW2, NW3 may include silicon germanium (SiGe).

Each of the first to third gate electrodes G1, G2, G3 may extend in the second horizontal direction DR2 on the active pattern 101 and field insulating layer 105. The third gate electrode G3 may be spaced apart from the first gate electrode G1 in the first horizontal direction DR1. The second gate electrode G2 may be spaced apart from the third gate electrode G3 in the first horizontal direction DR1. That is, the third gate electrode G3 may be disposed between the first gate electrode G1 and the second gate electrode G2. The first gate electrode G1 may surround the first plurality of nanosheets NW1. The second gate electrode G2 may surround the second plurality of nanosheets NW2. The third gate electrode G3 may surround the third plurality of nanosheets NW3. For example, on the active pattern 101, the upper surface of the second gate electrode G2 may be formed higher than the upper surface of the first gate electrode G1.

For example, each of the first to third gate electrodes G1, G2, G3 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. Each of the first to third gate electrodes G1, G2, G3 may include conductive metal oxides, conductive metal oxynitrides, or the like, and may include oxidized forms of aforementioned materials.

A first gate spacer 111 may extend in the second horizontal direction DR2 along both sidewalls of the first gate electrode G1 on the upper surface of the uppermost nanosheet of the first plurality of nanosheets NW1 and the field insulating layer 105. A second gate spacer 112 may extend in the second horizontal direction DR2 along both sidewalls of the second gate electrode G2 on the upper surface of the uppermost nanosheet of the second plurality of nanosheets NW2 and the field insulating layer 105. A third gate spacer 113 may extend in the second horizontal direction DR2 along both sidewalls of the active cut 160 on the upper surface of the uppermost nanosheet of the third plurality of nanosheets NW3 and the field insulating layer 105. For example, each of the first to third gate spacers 111, 112, 113 may include at least one of silicon nitride (SiN), silicon oxynitride (SiON), silicon oxide (SiO₂) silicon oxycarbonitride (SiOCN), silicon boron nitride (SiBN), silicon oxyboron nitride (SiOBN), silicon oxycarbide (SiOC), and combinations thereof. However, example embodiments are not limited thereto.

A first source/drain region SD1 may be disposed between the first gate electrode G1 and the third gate electrode G3 on the active pattern 101. In this regard, the first source/drain region SD1 may be disposed between the first gate electrode G1 and the active cut 160 on the active pattern 101. The first source/drain region SD1 may be in contact with the sidewalls of each of the first and third plurality of nanosheets NW1, NW3 in the first horizontal direction DR1. A second source/drain region SD2 may be disposed between the third gate electrode G3 and the second gate electrode G2 on the active pattern 101. In this regard, the second source/drain region SD2 may be disposed between the active cut 160 and the second gate electrode G2 on the active pattern 101. The second source/drain region SD2 may be in contact with the sidewalls of each of the third and second plurality of nanosheets NW3, NW2 in the first horizontal direction DR1.

A first gate insulating layer 121 may be disposed between the first gate electrode G1 and the first gate spacer 111. The first gate insulating layer 121 may be disposed between the first gate electrode G1 and the first source/drain region SD1. The first gate insulating layer 121 may be disposed between the first gate electrode G1 and the active pattern 101. The first gate insulating layer 121 may be disposed between the first gate electrode G1 and the field insulating layer 105. The first gate insulating layer 121 may be disposed between the first gate electrode G1 and the first plurality of nanosheets NW1. A second gate insulating layer 122 may be disposed between the second gate electrode G2 and the second gate spacer 112. The second gate insulating layer 122 may be disposed between the second gate electrode G2 and the second source/drain region SD2. The second gate insulating layer 122 may be disposed between the second gate electrode G2 and the active pattern 101. The second gate insulating layer 122 may be disposed between the second gate electrode G2 and the field insulating layer 105. The second gate insulating layer 122 may be disposed between the second gate electrode G2 and the second plurality of nanosheets NW2. A third gate insulating layer 123 may be disposed between the third gate electrode G3 and the first source/drain region SD1. The third gate insulating layer 123 may be disposed between the third gate electrode G3 and the second source/drain region SD2. The third gate insulating layer 123 may be disposed between the third gate electrode G3 and the active pattern 101. The third gate insulating layer 123 may be disposed between the third gate electrode G3 and the field insulating layer 105. The third gate insulating layer 123 may be disposed between the third gate electrode G3 and the third plurality of nanosheets NW3.

For example, each of the first and third gate insulating layers 121, 123 may be in contact with the first source/drain region SD1, and each of the third and second gate insulating layers 123, 122 may be in contact with the second source/drain region SD2. However, example embodiments are not limited thereto. In some example embodiments, an inner spacer may be disposed between each of the first and third gate insulating layers 121, 123 and the first source/drain region SD1. Additionally, an inner spacer may be disposed between each of the third and second gate insulating layers 123, 122 and the second source/drain region SD2. In this case, for example, the inner spacer may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof.

Each of the first to third gate insulating layers 121, 122, 123 may include at least one of silicon oxide, silicon oxynitride, silicon nitride, or a high-k dielectric material having a dielectric constant greater than that of silicon oxide. High-k dielectric materials may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

A semiconductor device according to some example embodiments may include a Negative Capacitance (NC) FET utilizing a negative capacitor. For example, each of the first to third gate insulating layers 121, 122, 123 may include a ferroelectric material layer having ferroelectric properties and a paraelectric material layer having paraelectric properties.

The ferroelectric material layer may exhibit negative capacitance, while the paraelectric material layer may exhibit positive capacitance. For example, when two or more capacitors are connected in series and each of their capacitances has a positive value, the overall capacitance decreases relative to the capacitance of each individual capacitor. On the other hand, if the capacitances of at least one of the two or more capacitors connected in series has a negative value, the overall capacitance may be greater than the absolute value of each individual capacitance while still being positive.

When the ferroelectric material layer with negative capacitance and the paraelectric material layer with positive capacitance are connected in series, the overall capacitance value of the ferroelectric material layer and the paraelectric material layer connected in series may increase. By utilizing the increase in overall capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. As another example, hafnium zirconium oxide may be a material in which zirconium (Zr) is doped into hafnium oxide. In another example, hafnium zirconium oxide may be a compound of hafnium (Hf) and zirconium (Zr) with oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material layer contains, the type of dopant contained in the ferroelectric material layer may vary.

If the ferroelectric material layer includes hafnium oxide, the dopant included in the ferroelectric material layer may include, for example, at least one of gadolinium (Gd), silicon (Si), zirconium (Zr), aluminum (Al), and yttrium (Y).

If the dopant is aluminum (Al), the ferroelectric material layer may contain aluminum in a concentration of about 3 to 8 at % (atomic %). Here, the ratio of the dopant may be a ratio of aluminum relative to the sum of hafnium and aluminum.

If the dopant is silicon (Si), the ferroelectric material layer may contain 2 to 10 at % of silicon. If the dopant is yttrium (Y), the ferroelectric material layer may contain 2 to 10 at % of yttrium. If the dopant is gadolinium (Gd), the ferroelectric material layer may contain 1 to 7 at % of gadolinium. If the dopant is zirconium (Zr), the ferroelectric material layer may contain 50 to 80 at % of zirconium.

The paraelectric material layer may have paraelectric properties. The paraelectric material layer may include, for example, at least one of silicon oxide and a high-k metal oxide. The metal oxide included in the paraelectric material layer may include, for example, at least one of hafnium oxide, zirconium oxide, and aluminum oxide, but is not limited thereto.

The ferroelectric material layer and the paraelectric material layer may include the same material. While the ferroelectric material layer may have ferroelectric properties, the paraelectric material layer may not have ferroelectric properties. For example, if the ferroelectric material layer and the paraelectric material layer contain hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. For example, the thickness of the ferroelectric material layer may range from 0.5 to 10 nm, but is not limited thereto. Because each ferroelectric material may have a different critical thickness for exhibiting ferroelectric properties, the thickness of the ferroelectric material layer may vary depending on the specific ferroelectric material.

For example, each of the first to third gate insulating layers 121, 122, 123 may include a single ferroelectric material layer. In another example, each of the first to third gate insulating layers 121, 122, 123 may include a plurality of ferroelectric material layers spaced apart from each other. Each of the first to third gate insulating layers 121, 122, 123 may have a stacked layer structure in which the plurality of ferroelectric material layers are alternately stacked with the plurality of paraelectric material layers.

The etching stop layer 130 may be disposed on the upper surface of the field insulating layer 105. The etching stop layer 130 may be disposed on the sidewalls of each of the first to third gate spacers 111, 112, 113. The etching stop layer 130 may be disposed on the sidewalls of each of the first and second source/drain regions SD1, SD2 in the second horizontal direction DR2. For example, the etching stop layer 130 may be conformally formed. For example, the etching stop layer 130 may include at least one of aluminum oxide, aluminum nitride, hafnium oxide, zirconium oxide, silicon oxide, silicon nitride, silicon oxynitride, and low-k dielectric materials.

The first interlayer insulating layer 140 may be disposed on the etching stop layer 130. For example, the first interlayer insulating layer 140 may surround both sidewalls of each of the first and second source/drain regions SD1, SD2 in the second horizontal direction DR2. For example, the first interlayer insulating layer 140 may include at least one of silicon oxide, silicon nitride, silicon oxynitride, and a low-k dielectric material. The low-k dielectric material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, Amorphous Fluorinated Carbon, silica aerogels, silica xerogels, mesoporous silica, and combinations thereof, but example embodiments are not limited thereto.

The first source/drain contact CA1 may be disposed on the upper surface of the first source/drain region SD1. The first source/drain contact CA1 may be electrically connected to the first source/drain region SD1. For example, the first source/drain contact CA1 may include a first portion CA1_1 and a second portion CA1_2. The first portion CA1_1 of the first source/drain contact CA1 may be disposed on the upper surface of the first source/drain region SD1. The second portion CA1_2 of the first source/drain contact CA1 may protrude in the vertical direction DR3 from the upper surface of the first portion CA1_1 of the first source/drain contact CA1. The bottom surface of the second portion CA1_2 of the first source/drain contact CA1 may be in contact with the upper surface of the first portion CA1_1 of the first source/drain contact CA1. For example, the second portion CA1_2 of the first source/drain contact CA1 may be formed integrally with the first portion CA1_1 of the first source/drain contact CA1.

For example, a width in the second horizontal direction DR2 of the upper surface of the first portion CA1_1 of the first source/drain contact CA1 may be greater than a width in the second horizontal direction DR2 of the bottom surface of the second portion CA1_2 of the first source/drain contact CA1. For example, the upper surface of the first portion CA1_1 of the first source/drain contact CA1 may be formed on the same plane as the upper surface of the first interlayer insulating layer 140. For example, the uppermost surface of the first source/drain contact CA1 may be formed on the same plane as the uppermost surface of each of the first and third gate spacers 111, 113. In this regard, the upper surface of the second portion CA1_2 of the first source/drain contact CA1 may be formed on the same plane as the uppermost surface of each of the first and third gate spacers 111, 113.

The second source/drain contact CA2 may be disposed on the upper surface of the second source/drain region SD2. The second source/drain contact CA2 may be electrically connected to the second source/drain region SD2. For example, on the active pattern 101, the upper surface of the first source/drain contact CA1 may be formed higher than the upper surface of the second source/drain contact CA2. In this regard, on the active pattern 101, the upper surface of the second portion CA1_2 of the first source/drain contact CA1 may be formed higher than the upper surface of the second source/drain contact CA2.

For example, both sidewalls of the first source/drain contact CA1 in the first horizontal direction DR1 may be in contact with the etching stop layer 130. Additionally, both sidewalls of the second source/drain contact CA2 in the first horizontal direction DR1 may be in contact with the etching stop layer 130. However, example embodiments are not limited thereto. In some example embodiments, the first interlayer insulating layer 140 may be disposed between both sidewalls of the first source/drain contact CA1 in the first horizontal direction DR1 and the etching stop layer 130. Additionally, the first interlayer insulating layer 140 may be disposed between both sidewalls of the second source/drain contact CA2 in the first horizontal direction DR1 and the etching stop layer 130. Each of the first and second source/drain contacts CA1, CA2 may include a conductive material.

In FIGS. 2 and 4, although each of the first and second source/drain contacts CA1, CA2 is shown as being formed as a single layer, example embodiments are not limited thereto. In some example embodiments, each of the first and second source/drain contacts CA1, CA2 may be formed as multiple layers. A silicide layer SL may be disposed along the interface between the first source/drain contact CA1 and the first source/drain region SD1. Further, the silicide layer SL may be disposed along the interface between the second source/drain contact CA2 and the second source/drain region SD2. For example, the silicide layer SL may include a metal silicide material.

A contact via V1 may be disposed on the uppermost surface of the first source/drain contact CA1. That is, the contact via V1 may be disposed on the upper surface of the second portion CA1_2 of the first source/drain contact CA1. The contact via V1 may be electrically connected to the first source/drain contact CA1. For example, the contact via V1 may be in contact with the uppermost surface of the first source/drain contact CA1. In this regard, the contact via V1 may be in contact with the upper surface of the second portion CA1_2 of the first source/drain contact CA1. However, example embodiments are not limited thereto. In some example embodiments, a layer including a conductive material may be disposed between the contact via V1 and the uppermost surface of the first source/drain contact CA1. For example, the contact via V1 may be in contact with the uppermost surface of each of the first and third gate spacers 111, 113. However, example embodiments are not limited thereto. The contact via V1 may include a conductive material.

A gate contact CB may be disposed on the upper surface of the second gate electrode G2. The gate contact CB may be electrically connected to the second gate electrode G2. For example, the gate contact CB may be in contact with the upper surface of the second gate electrode G2. For example, the gate contact CB may be in contact with the uppermost surface of each of the third and second gate spacers 113, 112. However, example embodiments are not limited thereto. The gate contact CB may include a conductive material. For example, the gate contact CB may include the same material as the contact via V1. This is because the gate contact CB and the contact via V1 are formed through the same fabrication process. For example, the upper surface of the gate contact CB may be formed on the same plane as the upper surface of the contact via V1. For example, the bottom surface of the gate contact CB may be formed on the same plane as the bottom surface of the contact via V1.

The second interlayer insulating layer 150 may be disposed on the upper surface of the first interlayer insulating layer 140. For example, the second interlayer insulating layer 150 may be in contact with the upper surface of the first interlayer insulating layer 140. The second interlayer insulating layer 150 may be in contact with the upper surface of the first gate electrode G1. The second interlayer insulating layer 150 may be in contact with the uppermost surface of the first gate insulating layer 121. The second interlayer insulating layer 150 may be in contact with each of the first to third gate spacers 111, 112, 113. The second interlayer insulating layer 150 may be in contact with at least a portion of the upper surface of the first portion CA1_1 of the first source/drain contact CA1. The second interlayer insulating layer 150 may be in contact with both sidewalls of the second portion CA1_2 of the first source/drain contact CA1 in the second horizontal direction DR2. On the active pattern 101, the second interlayer insulating layer 150 may be in contact with the upper surface of the second source/drain contact CA2. The second interlayer insulating layer 150 may surround the sidewalls of each of the contact via V1 and the gate contact CB.

For example, the bottom surface of the second interlayer insulating layer 150 may be formed lower than the uppermost surface of the first source/drain contact CA1. That is, the bottom surface of the second interlayer insulating layer 150 may be formed lower than the upper surface of the second portion CA1_2 of the first source/drain contact CA1. On the active pattern 101, the bottom surface of the second interlayer insulating layer 150 may be formed lower than the upper surface of the second gate electrode G2. For example, the upper surface of the second interlayer insulating layer 150 may be formed on the same plane as each of the upper surface of the contact via V1 and the upper surface of the gate contact CB.

For example, the second interlayer insulating layer 150 may be formed as a single layer. The second interlayer insulating layer 150 may include an insulating material. For example, the second interlayer insulating layer 150 may include any one of silicon nitride (SiN), silicon oxynitride (SiON), silicon carbonitride (SiCN), silicon oxide (SiO₂), silicon oxycarbonitride (SiOCN), and silicon oxycarbide (SiOC). However, example embodiments are not limited thereto. For example, the second interlayer insulating layer 150 may include a different material from that of the first interlayer insulating layer 140. However, example embodiments are not limited thereto.

An active cut 160 may extend in the second horizontal direction DR2 between the first gate electrode G1 and the second gate electrode G2. The active cut 160 may be spaced apart from the first gate electrode G1 in the first horizontal direction DR1. The second gate electrode G2 may be spaced apart from the active cut 160 in the first horizontal direction DR1. The active cut 160 may penetrate each of the third gate electrode G3, the third gate insulating layer 123, and the third plurality of nanosheets NW3 in the vertical direction DR3 on the upper surface of the substrate 100. For example, at least a portion of the active cut 160 may be disposed inside the substrate 100. For example, the active cut 160 may divide the active pattern 101 in the first horizontal direction DR1. However, example embodiments are not limited thereto.

For example, both sidewalls of the active cut 160 in the first horizontal direction DR1 may be in contact with each of the active pattern 101, the third gate electrode G3, the third gate insulating layer 123, and the third plurality of nanosheets NW3. For example, the third gate spacer 113 may be in contact with both sidewalls of the active cut 160 in the first horizontal direction DR1 on the upper surface of the uppermost nanosheet of the third plurality of nanosheets NW3. For example, both sidewalls of the active cut 160 in the first horizontal direction DR1 may be in contact with the second interlayer insulating layer 150. For example, the active cut 160 may overlap with the contact via V1 in the first horizontal direction DR1. Additionally, the active cut 160 may overlap with the gate contact CB in the first horizontal direction DR1. For example, the active cut 160 may be spaced apart from the contact via V1 in the first horizontal direction DR1. However, example embodiments are not limited thereto.

For example, the uppermost surface of the first source/drain contact CA1 may be formed lower than the upper surface of the active cut 160. That is, the upper surface of the second portion CA1_2 of the first source/drain contact CA1 may be formed lower than the upper surface of the active cut 160. Additionally, on the active pattern 101, the upper surface of the second source/drain contact CA2 may be formed lower than the upper surface of the active cut 160. For example, the uppermost surface of each of the first to third gate spacers 111, 112, 113 may be formed lower than the upper surface of the active cut 160. For example, the upper surface of the active cut 160 may be formed on the same plane as the upper surface of the contact via V1. For example, the upper surface of the active cut 160 may be formed on the same plane as the upper surface of the second interlayer insulating layer 150. The upper surface of the active cut 160 may be formed on the same plane as the upper surface of the gate contact CB. However, example embodiments are not limited thereto. In some example embodiments, the upper surface of the active cut 160 may be formed lower than the upper surface of the gate contact CB. The active cut 160 may include an insulating material. For example, the active cut 160 may include any one of silicon nitride (SiN), silicon oxynitride (SiON), silicon carbonitride (SiCN), silicon oxide (SiO₂), silicon oxycarbonitride (SiOCN), and silicon oxycarbide (SiOC), but example embodiments are not limited thereto.

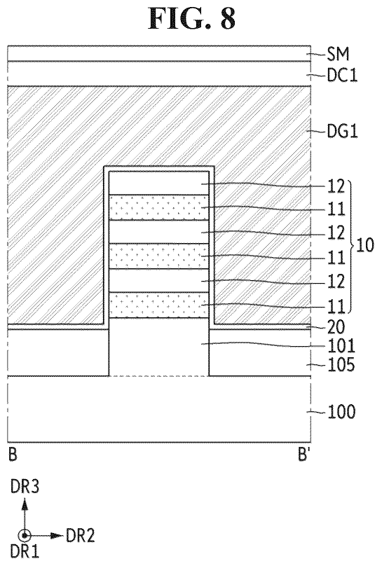

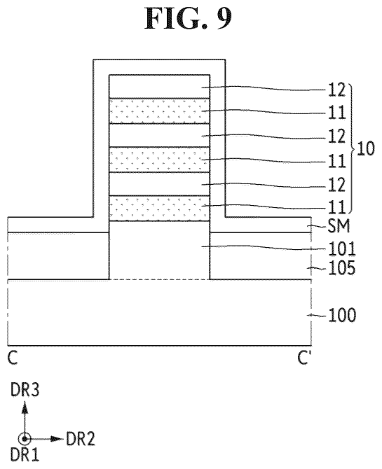

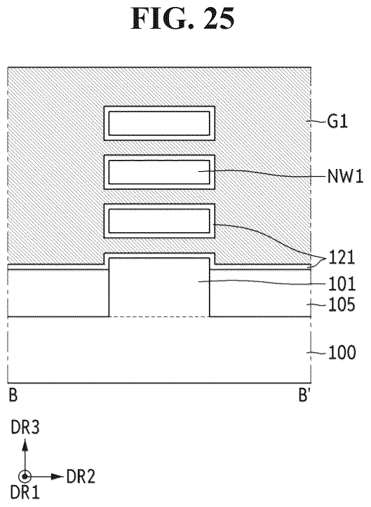

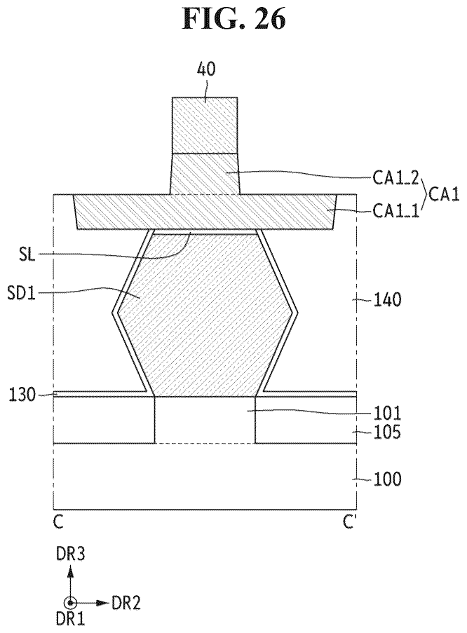

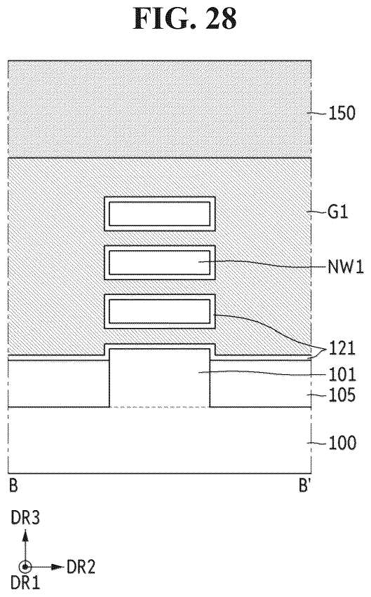

Hereinafter, the fabrication method of a semiconductor device according to some example embodiments will be described with reference to FIGS. 2 to 32.

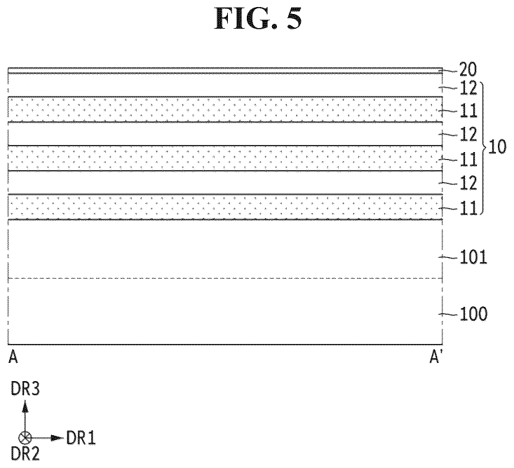

FIGS. 5 to 32 are intermediate stage diagrams for explaining the fabrication method of a semiconductor device according to some example embodiments.

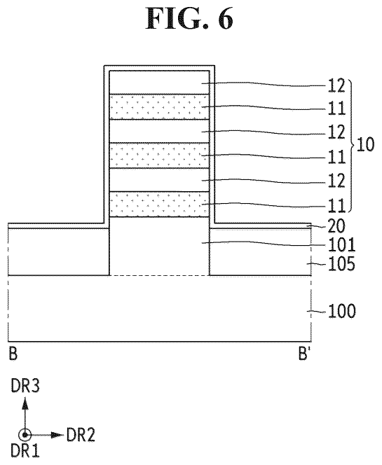

Referring to FIGS. 5 and 6, a stacked structure 10 may be formed on the substrate 100. The stacked structure 10 may include a first semiconductor layer 11 and a second semiconductor layer 12 alternately stacked on the substrate 100. For example, a first semiconductor layer 11 may be formed at the lowermost portion of the stacked structure 10, and the second semiconductor layer 12 may be formed at the uppermost portion of the stacked structure 10. However, example embodiments are not limited thereto. In some example embodiments, the first semiconductor layer 11 may be formed at the uppermost portion of the stacked structure 10. The first semiconductor layer 11 may include, for example, silicon germanium (SiGe). The second semiconductor layer 12 may include, for example, silicon (Si).

A portion of the stacked structure 10 may be etched. While the stacked structure 10 is being etched, a portion of the substrate 100 may also be etched. Through this etching process, an active pattern 101 may be defined beneath the stacked structure 10 on the substrate 100. The active pattern 101 may extend in the first horizontal direction DR1. A field insulating layer 105 may be formed on the upper surface of the substrate 100. The field insulating layer 105 may surround the sidewalls of the active pattern 101. For example, the upper surface of the active pattern 101 may be formed higher than the upper surface of the field insulating layer 105. A pad oxide layer 20 may be formed to cover the upper surface of the field insulating layer 105, the exposed sidewalls of the active pattern 101, and the sidewalls and upper surface of the stacked structure 10. For example, the pad oxide layer 20 may be formed conformally. The pad oxide layer 20 may include, for example, silicon oxide (SiO₂).

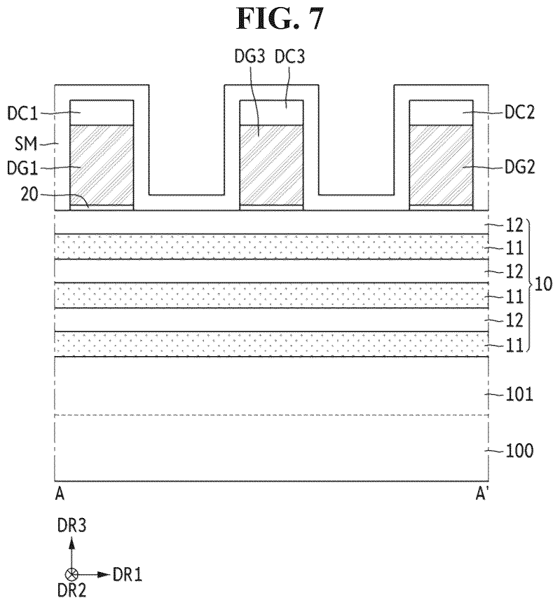

Referring to FIGS. 7 to 9, first to third dummy gates DG1, DG2, DG3 and first to third dummy capping patterns DC1, DC2, DC3 extending in the second horizontal direction DR2 may be formed on the pad oxide layer 20 over the stacked structure 10 and field insulating layer 105. For example, the third dummy gate DG3 may be spaced apart from the first dummy gate DG1 in the first horizontal direction DR1. The second dummy gate DG2 may be spaced apart from the third dummy gate DG3 in the first horizontal direction DR1. That is, the third dummy gate DG3 may be formed between the first dummy gate DG1 and the second dummy gate DG2. The first dummy capping pattern DC1 may be disposed on the first dummy gate DG1. The second dummy capping pattern DC2 may be disposed on the second dummy gate DG2. The third dummy capping pattern DC3 may be disposed on the third dummy gate DG3.

While the first to third dummy gates DG1, DG2, DG3 and the first to third dummy capping patterns DC1, DC2, DC3 are being formed, the remaining pad oxide layer 20 on the substrate 100 may be removed, except for the portion overlapping with each of the first to third dummy gates DG1, DG2, DG3 in the vertical direction DR3. A spacer material layer SM may be formed to cover the sidewalls of each of the first to third dummy gates DG1, DG2, DG3, the sidewalls and upper surface of each of the first to third dummy capping patterns DC1, DC2, DC3, the exposed sidewalls and upper surface of the stacked structure 10, and the upper surface of the field insulating layer 105. For example, the spacer material layer SM may be formed conformally. The spacer material layer SM may include, for example, at least one of silicon nitride (SiN), silicon oxycarbonitride (SiOCN), silicon boron carbonitride (SiBCN), silicon carbonitride (SiCN), silicon oxynitride (SiON), and combinations thereof.

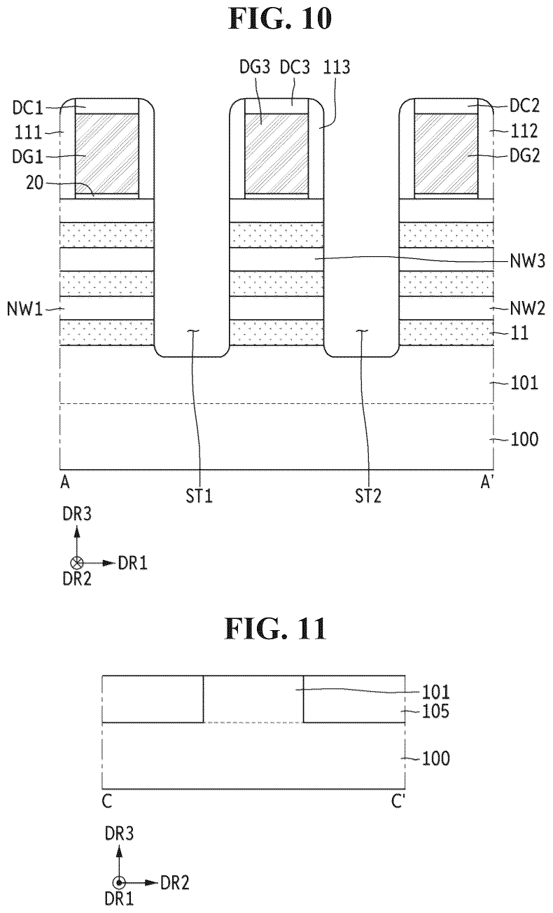

Referring to FIGS. 10 and 11, the stacked structure 10 (see FIG. 7) may be etched using the first to third dummy gates DG1, DG2, DG3 and the first to third dummy capping patterns DC1, DC2, DC3 as masks to form the first and second source/drain trenches ST1, ST2, respectively. For example, the first source/drain trench ST1 may be formed between the first dummy gate DG1 and the third dummy gate DG3 on the active pattern 101. The second source/drain trench ST2 may be formed between the third dummy gate DG3 and the first dummy gate DG1 on the active pattern 101. For example, while each of the first and second source/drain trenches ST1, ST2 is being formed, a portion of the spacer material layer SM (see FIG. 7) formed on the upper surface of each of the first to third dummy capping patterns DC1, DC2, DC3 and a portion of each of the first to third dummy capping patterns DC1, DC2, DC3 may be etched.

For example, the spacer material layer SM (see FIG. 7) remaining on the sidewalls of each of the first to third dummy capping patterns DC1, DC2, DC3 and the first to third dummy gates DG1, DG2, DG3 may be referred to as the first to third gate spacers 111, 112, 113. For example, after the first and second source/drain trenches ST1, ST2 are each formed, the second semiconductor layer 12 (see FIG. 7) remaining beneath each of the first to third dummy gates DG1, DG2, DG3 may be referred to as each of the first to third plurality of nanosheets NW1, NW2, NW3. That is, the third plurality of nanosheets NW3 may be formed between the first plurality of nanosheets NW1 and the second plurality of nanosheets NW2.

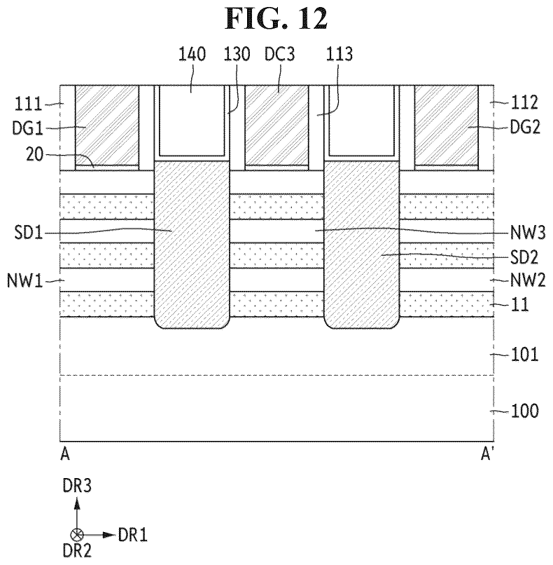

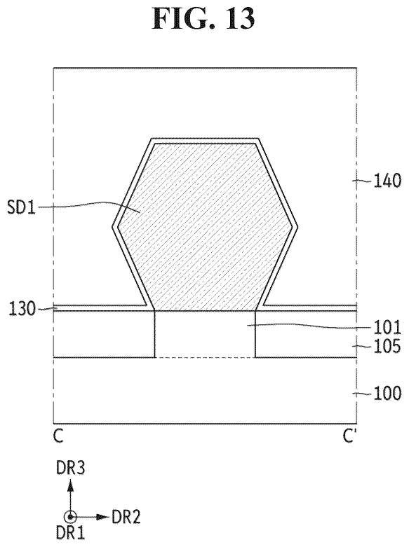

Referring to FIGS. 12 and 13, a first source/drain region SD1 may be formed inside the first source/drain trench ST1 (see FIG. 10), and the second source/drain region SD2 may be formed inside the second source/drain trench ST2 (see FIG. 10). The etching stop layer 130 and the first interlayer insulating layer 140 may be formed sequentially on the upper surface of the field insulating layer 105, the surface of each of the first and second source/drain regions SD1, SD2, the exposed surface of each of the first to third gate spacers 111, 112, 113, and the upper surface of each of the first to third dummy capping patterns DC1, DC2, DC3 (see FIG. 10). For example, the etching stop layer 130 may be formed conformally. A planarization process may be performed to expose the upper surface of each of the first to third dummy gates DG1, DG2, DG3.

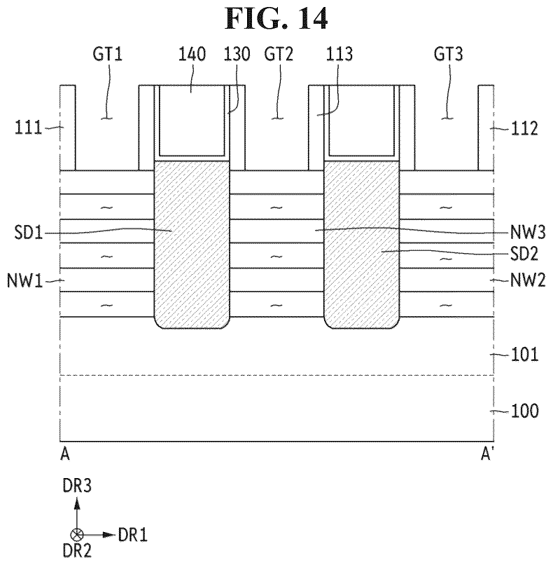

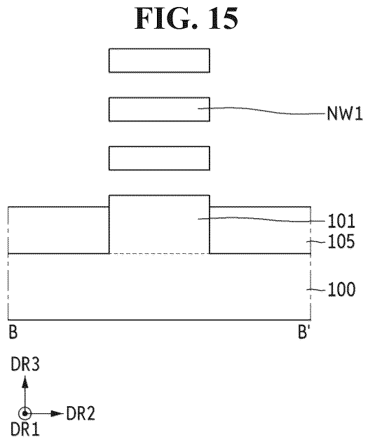

Referring to FIGS. 14 and 15, each of the first to third dummy gates DG1, DG2, DG3 (see FIG. 12), the pad oxide layer 20 (see FIG. 12), and the first semiconductor layer 11 (see FIG. 12) may be etched. The portion in which each of the first dummy gate DG1 (see FIG. 12), the pad oxide layer 20 (see FIG. 12), and the first semiconductor layer 11 (see FIG. 12) is etched may be referred to as the first gate trench GT1. The portion in which each of the second dummy gate DG2 (see FIG. 12), the pad oxide layer 20 (see FIG. 12), and the first semiconductor layer 11 (see FIG. 12) is etched may be referred to as the second gate trench GT2. The portion in which each of the third dummy gate DG3 (see FIG. 12), the pad oxide layer 20 (see FIG. 12), and the first semiconductor layer 11 (see FIG. 12) is etched may be referred to as the third gate trench GT3.

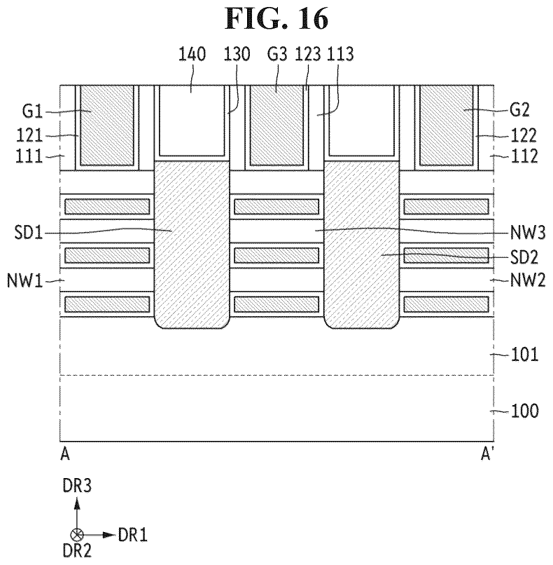

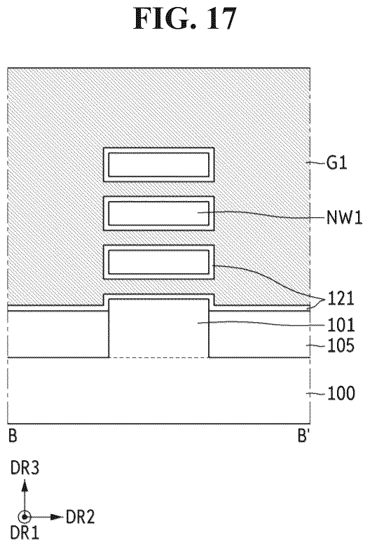

Referring to FIGS. 16 and 17, a first gate insulating layer 121 and a first gate electrode G1 may be formed sequentially inside the first gate trench GT1 (see FIG. 14). The first gate electrode G1 may surround the first plurality of nanosheets NW1. A second gate insulating layer 122 and a second gate electrode G2 may be formed sequentially inside the second gate trench GT2 (see FIG. 14). The second gate electrode G2 may surround the second plurality of nanosheets NW2. A third gate insulating layer 123 and a third gate electrode G3 may be formed sequentially inside the third gate trench GT3 (see FIG. 14). The third gate electrode G3 may surround the third plurality of nanosheets NW3.

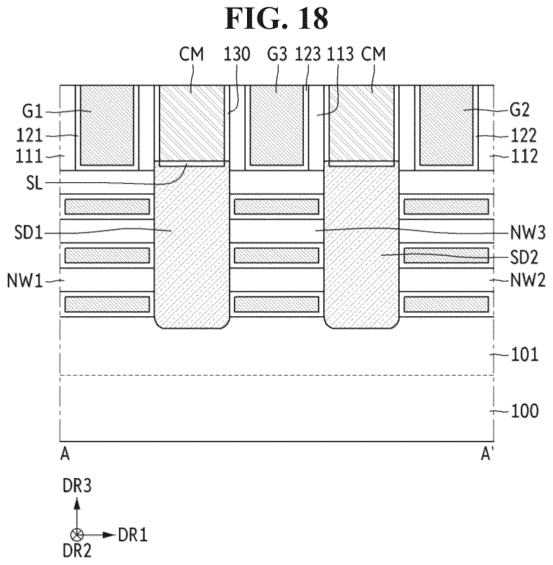

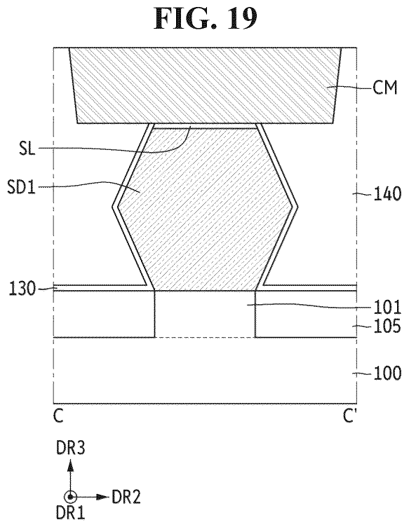

Referring to FIGS. 18 and 19, a contact material layer CM may be formed on the upper surface of each of the first and second source/drain regions SD1, SD2 inside the first interlayer insulating layer 140. For example, the sidewall of the contact material layer CM in the first horizontal direction DR1 may be in contact with the etching stop layer 130. For example, the upper surface of the contact material layer CM may be formed on the same plane as the upper surface of the first interlayer insulating layer 140. Additionally, the upper surface of the contact material layer CM may be formed on the same plane as the upper surface of each of the first to third gate electrodes G1, G2, G3, the first to third gate spacers 111, 112, 113, and the first to third gate insulating layers 121, 122, 123. The contact material layer CM may include the same material as each of the first and second source/drain contacts CA1, CA2 shown in FIG. 2. Further, a silicide layer SL may be formed along the interface between each of the first and second source/drain regions SD1, SD2 and the contact material layer CM.

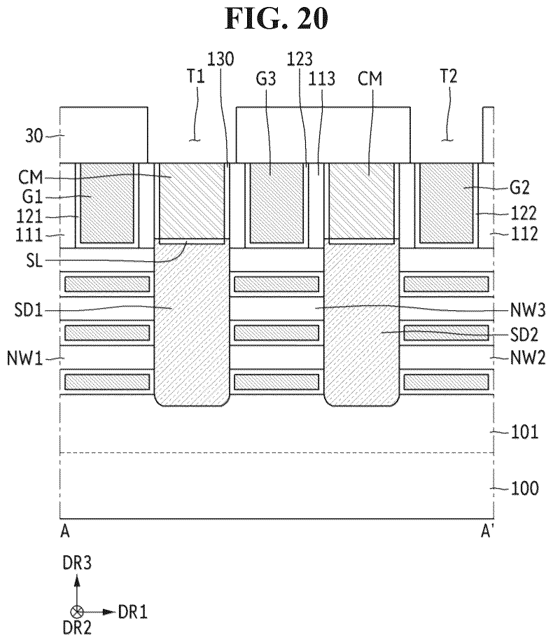

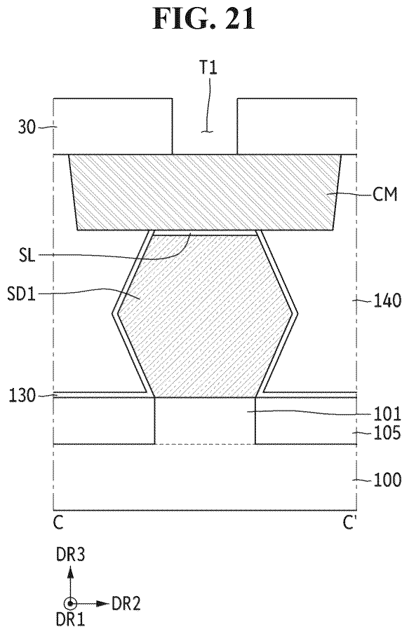

Referring to FIGS. 20 and 21, a photoresist pattern 30 may be formed on the upper surface of each of the first to third gate electrodes G1, G2, G3, the first to third gate spacers 111, 112, 113, the first to third gate insulating layers 121, 122, 123, the etching stop layer 130, the first interlayer insulating layer 140, and the contact material layer CM. For example, the photoresist pattern 30 may include photoresist material or Spin-On Hardmask (SOH).

For example, the photoresist pattern 30 may include a first trench T1 and a second trench T2. For example, the first trench T1 may be formed between the first gate electrode G1 and the third gate electrode G3 on the active pattern 101. The first trench T1 may expose a portion of the upper surface of the contact material layer CM formed between the first gate electrode G1 and the third gate electrode G3. For example, the first trench T1 may expose a portion of each of the first and third gate spacers 111, 113. For example, the second trench T2 may expose the upper surface of the second gate electrode G2 on the active pattern 101. For example, the second trench T2 may expose a portion of each of the third and second gate spacers 113, 112.

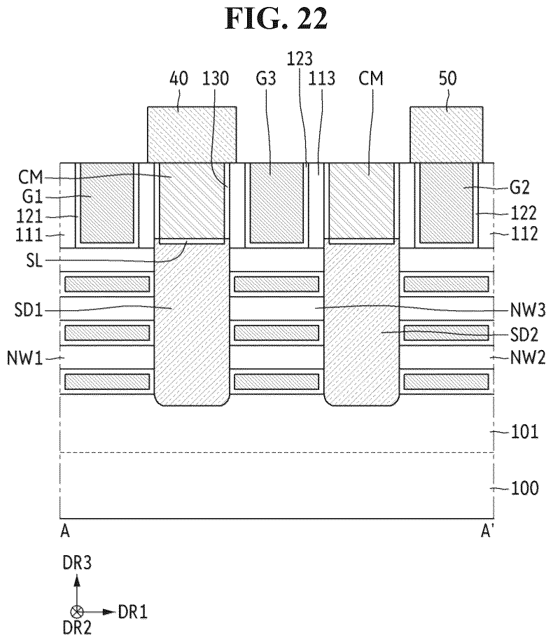

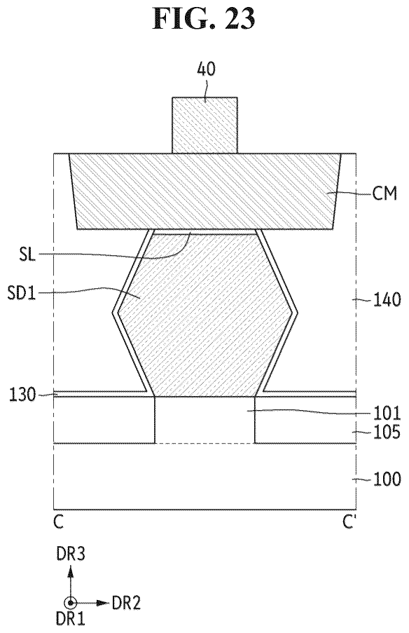

Referring to FIGS. 22 and 23, a first sacrificial pattern 40 may be formed inside the first trench T1 (see FIGS. 20 and 21), and a second sacrificial pattern 50 may be formed inside the second trench T2 (see FIG. 20). The first sacrificial pattern 40 and the second sacrificial pattern 50 may include the same material. Each of the first sacrificial pattern 40 and the second sacrificial pattern 50 may include a material having an etch selectivity with respect to each of the second interlayer insulating layer 150 and the active cut 160 shown in FIG. 2. For example, each of the first sacrificial pattern 40 and the second sacrificial pattern 50 may include silicon oxide (SiO₂), but example embodiments are not limited thereto. The photoresist pattern 30 (see FIGS. 20 and 21) may be etched.

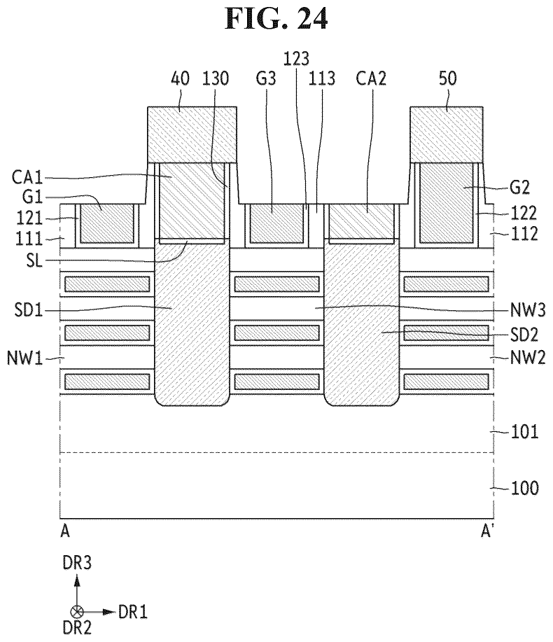

Referring to FIGS. 24 to 26, an etching process may be performed using each of the first sacrificial pattern 40 and the second sacrificial pattern 50 as a mask. After such an etching process is performed, the remaining contact material layer CM (see FIGS. 22 and 23) between the first gate electrode G1 and the third gate electrode G3 may be the first source/drain contact CA1. Further, after such an etching process is performed, the remaining contact material layer CM (see FIG. 22) between the third gate electrode G3 and the second gate electrode G2 may be the second source/drain contact CA2.

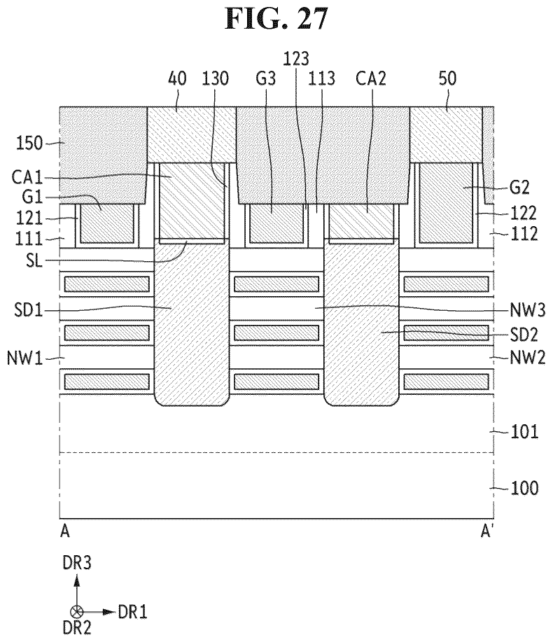

Referring to FIGS. 27 to 29, a second interlayer insulating layer 150 may be formed on the etched portion in FIGS. 24 to 26. For example, the upper surface of the second interlayer insulating layer 150 may be formed on the same plane as the upper surface of each of the first sacrificial pattern 40 and the second sacrificial pattern 50.

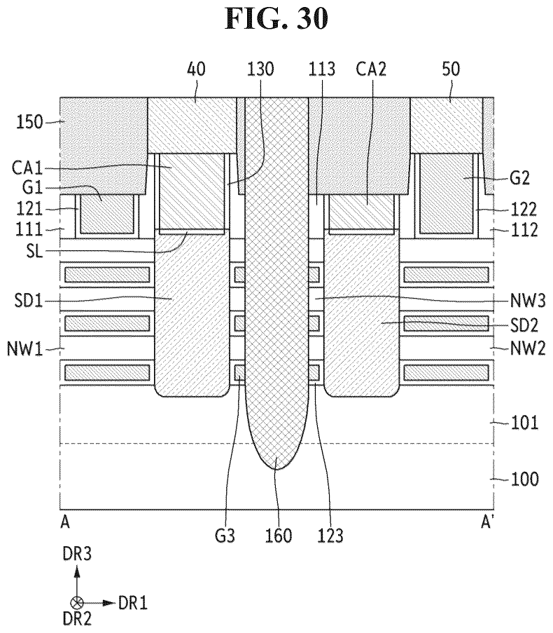

Referring to FIG. 30, an active cut 160 may be formed to penetrate the second interlayer insulating layer 150, the third gate electrode G3, the third gate insulating layer 123, the third plurality of nanosheets NW3, and the active pattern 101 in the vertical direction DR3 The active cut 160 may extend in the vertical direction DR3 into the substrate 100. The active cut 160 may extend in the second horizontal direction DR2. For example, the upper surface of the active cut 160 may be formed on the same plane as the upper surface of each of the second interlayer insulating layer 150, the first sacrificial pattern 40, and the second sacrificial pattern 50.

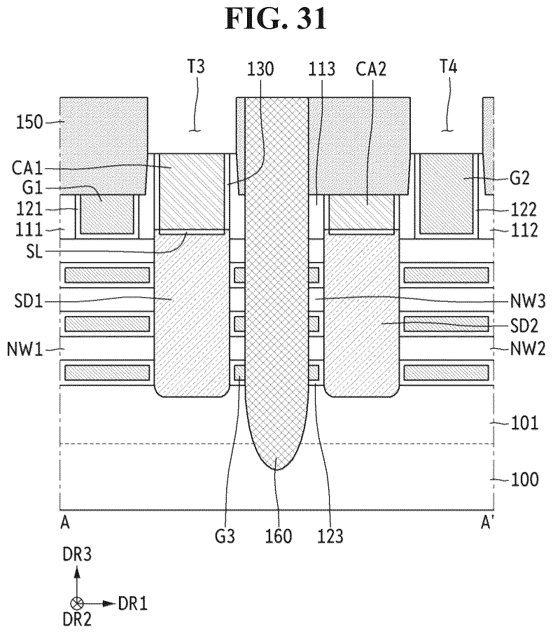

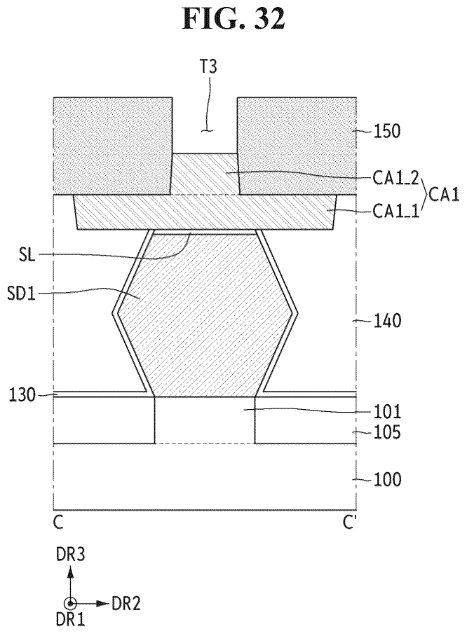

Referring to FIGS. 31 and 32, each of the first sacrificial pattern 40 (see FIG. 30) and the second sacrificial pattern 50 (see FIG. 30) may be etched. The portion in which the first sacrificial pattern 40 (see FIG. 30) is etched may be referred to as a third trench T3, and the portion in which the second sacrificial pattern 50 (see FIG. 30) is etched may be referred to as a fourth trench T4.

Referring to FIGS. 2 to 4, a contact via V1 may be formed inside the third trench T3 (see FIGS. 31 and 32), and a gate contact CB may be formed inside the fourth trench T4 (see FIG. 31). For example, the contact via V1 and the gate contact CB may be formed through the same fabrication process. A planarization process may be performed. As a result, the upper surface of each of the contact via V1, the gate contact CB, the second interlayer insulating layer 150, and the active cut 160 may be formed on the same plane. Through this fabrication process, the semiconductor device shown in FIGS. 2 to 4 may be fabricated.

After each of the source/drain contact and the gate contact has been formed, if the active cut is formed while the upper surface of each of the source/drain contact and the gate contact is exposed, residuals of the active cut may remain on the upper surface of each of the source/drain contact and the gate contact, thereby reducing the electrical reliability of each of the source/drain contact and the gate contact. In the fabrication method of a semiconductor device according to some example embodiments, after the first source/drain contact CA1 is formed, the first sacrificial pattern 40 and the second interlayer insulating layer 150 may be formed on the upper surface of the first source/drain contact CA1, and the second sacrificial pattern 50 and the second interlayer insulating layer 150 may be formed on the upper surface of the second gate electrode G2. The active cut 160 may be formed. Accordingly, the fabrication method of the semiconductor device according to some example embodiments may prevent residuals of the active cut 160 from remaining on the upper surfaces of the first source/drain contact CA1 and the second gate electrode G2, thereby improving the electrical reliability of each of the first source/drain contact CA1 and the gate contact CB. In the semiconductor device according to some example embodiments fabricated using the fabrication method described above, the uppermost surface of the first source/drain contact CA1 may be formed lower than the upper surface of the active cut 160. Further, the upper surfaces of the contact via V1 on the upper surface of the first source/drain contact CA1, the gate contact CB on the upper surface of the second gate electrode G2, and the active cut 160 may each be formed on the same plane.

Hereinafter, the fabrication method of a semiconductor device according to some example embodiments will be described with reference to FIGS. 2 to 4, FIG. 33 and FIG. 34. The description will focus on the differences from the fabrication method of the semiconductor device shown in FIGS. 5 to 32.

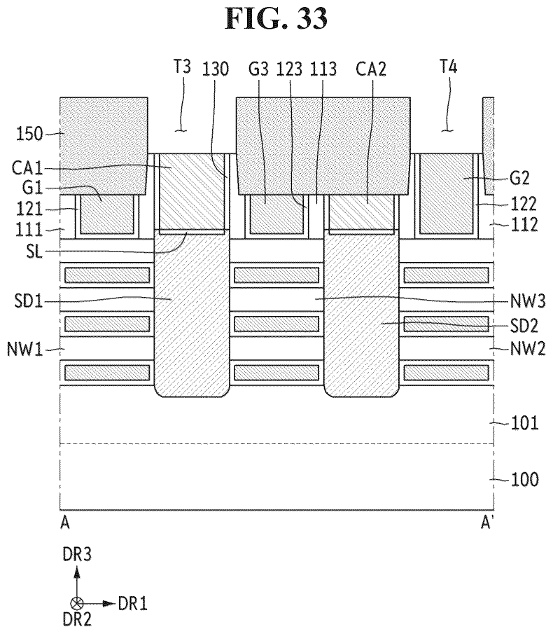

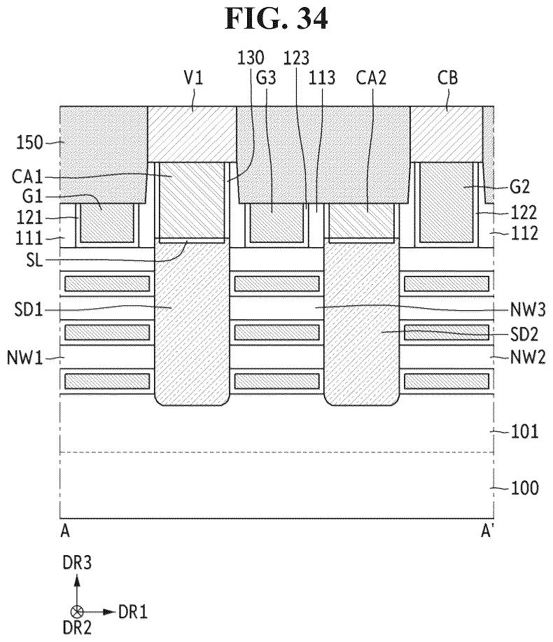

FIGS. 33 and 34 are intermediate stage diagrams for explaining the fabrication method of a semiconductor device according to some example embodiments.

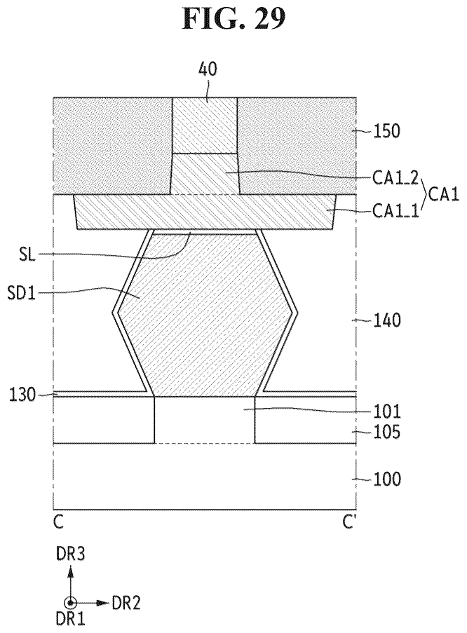

Referring to FIG. 33, after performing the fabrication process shown in FIGS. 5 to 29, each of the first sacrificial pattern 40 (see FIG. 27 and FIG. 29) and the second sacrificial pattern 50 (see FIG. 27) may be etched. The portion in which the first sacrificial pattern 40 (see FIG. 27 and FIG. 29) is etched may be referred to as the third trench T3, and the portion in which the second sacrificial pattern 50 (see FIG. 27) is etched may be referred to as the fourth trench T4.

Referring to FIG. 34, a contact via V1 may be formed inside the third trench T3 (see FIG. 33) and a gate contact CB may be formed inside the fourth trench T4 (see FIG. 33). For example, the contact via V1 and the gate contact CB may be formed through the same fabrication process. A planarization process may be performed. As a result, the upper surface of each of the contact via V1, the gate contact CB, and the second interlayer insulating layer 150 may be formed on the same plane.

Referring to FIGS. 2 to 4, an active cut 160 may be formed to penetrate the second interlayer insulating layer 150, the third gate electrode G3, the third gate insulating layer 123, the third plurality of nanosheets NW3, and the active pattern 101 in the vertical direction DR3. The active cut 160 may extend in the vertical direction DR3 into the substrate 100. The active cut 160 may extend in the second horizontal direction DR2. For example, the upper surface of the active cut 160 may be formed on the same plane as the upper surface of each of the contact via V1, the gate contact CB, and the second interlayer insulating layer 150. Through this fabrication process, the semiconductor device shown in FIGS. 2 to 4 may be fabricated.

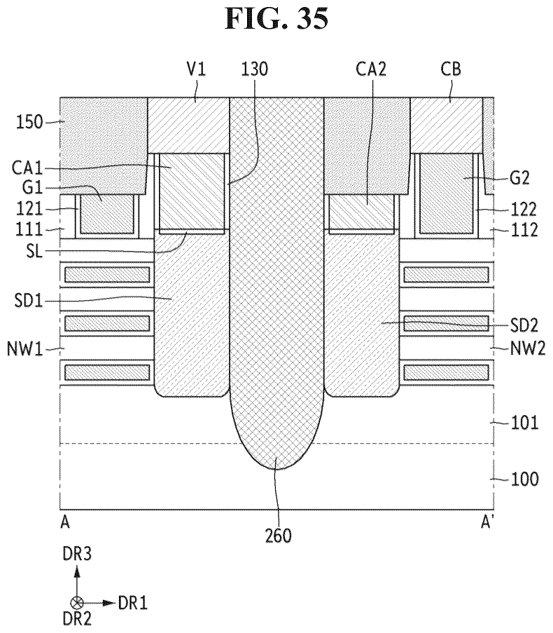

Hereinafter, a semiconductor device according to some example embodiments will be described with reference to FIG. 35. The description will focus on the differences from the semiconductor device shown in FIGS. 1 to 4.

FIG. 35 is a cross-sectional view for explaining a semiconductor device according to some example embodiments.

Referring to FIG. 35, in the semiconductor device according to some example embodiments, both sidewalls of the active cut 260 in the first horizontal direction DR1 may be in contact with the first and second source/drain regions SD1, SD2.

For example, both sidewalls of the active cut 260 in the first horizontal direction DR1 may be in contact with the etching stop layer 130. For example, one sidewall of the active cut 260 in the first horizontal direction DR1 may be in contact with the contact via V1.

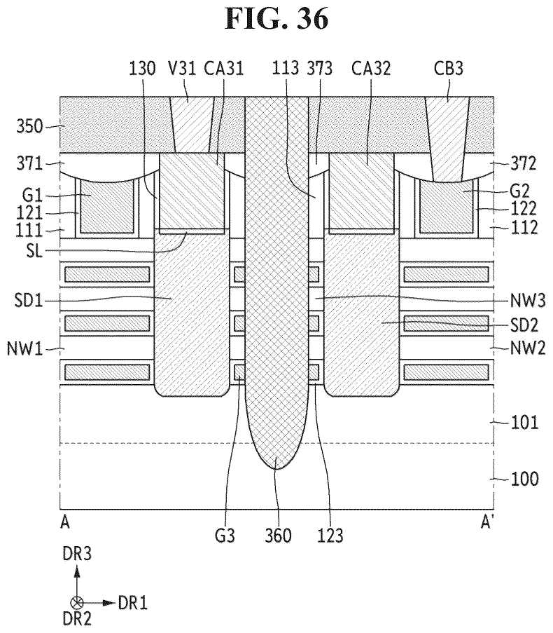

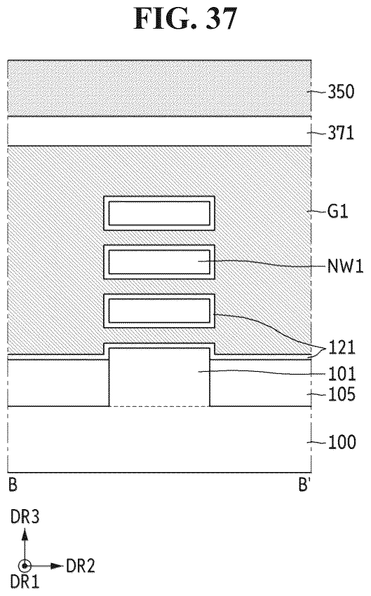

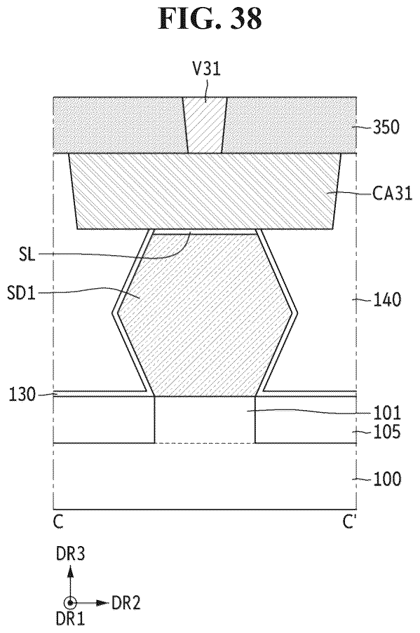

Hereinafter, a semiconductor device according to some example embodiments will be described with reference to FIGS. 36 to 38. The description will focus on the differences from the semiconductor device shown in FIGS. 1 to 4.

FIGS. 36 to 38 are cross-sectional views for explaining a semiconductor device according to some example embodiments.

Referring to FIGS. 36 to 38, in a semiconductor device according to some example embodiments, first to third capping patterns 371, 372, 373 may be disposed on the bottom surface of the second interlayer insulating layer 350.

For example, the first capping pattern 371 may extend in the second horizontal direction DR2 on the first gate spacer 111, the first gate electrode G1, the first gate insulating layer 121, and the etching stop layer 130. The bottom surface of the first capping pattern 371 may be in contact with the first gate spacer 111, the first gate electrode G1, the first gate insulating layer 121, and the etching stop layer 130. The second capping pattern 372 may extend in the second horizontal direction DR2 on the second gate spacer 112, the second gate electrode G2, the second gate insulating layer 122, and the etching stop layer 130. The bottom surface of the second capping pattern 372 may be in contact with the second gate spacer 112, the second gate electrode G2, the second gate insulating layer 122, and the etching stop layer 130.

For example, the third capping pattern 373 may extend in the second horizontal direction DR2 on the third gate spacer 113 and the etching stop layer 130. The bottom surface of the third capping pattern 373 may be in contact with the third gate spacer 113 and the etching stop layer 130. For example, the third capping pattern 373 may be in contact with both sidewalls of the active cut 360 in the first horizontal direction DR1. For example, the upper surface of each of the first to third capping patterns 371, 372, 373 may be formed lower than the upper surface of the active cut 360. For example, each of the first to third capping patterns 371, 372, 373 may include at least one of silicon nitride (SiN), silicon oxynitride (SiON), silicon oxide (SiO₂), silicon carbonitride (SiCN), silicon oxycarbonitride (SiOCN), and combinations thereof. However, example embodiments are not limited thereto.

For example, the upper surface of each of the first and second source/drain contacts CA31, CA32 may be formed on the same plane as the upper surface of each of the first to third capping patterns 371, 372, 373. For example, the second interlayer insulating layer 350 may be disposed on the upper surface of each of the first interlayer insulating layer 140, the first and second source/drain contacts CA31, CA32, and the first to third capping patterns 371, 372, 373. The second interlayer insulating layer 350 may be in contact with both sidewalls of the active cut 360 in the first horizontal direction DR1. For example, the upper surface of the second interlayer insulating layer 350 may be formed on the same plane as the upper surface of the active cut 360.

For example, the contact via V31 may penetrate the second interlayer insulating layer 350 in the vertical direction DR3 to connect to the first source/drain contact CA31. The contact via V31 may be in contact with the upper surface of the first source/drain contact CA31. The contact via V31 may overlap with the active cut 360 in the first horizontal direction DR1. For example, the gate contact CB3 may penetrate the second interlayer insulating layer 350 and the second capping pattern 372 in the vertical direction DR3 to connect to the second gate electrode G2. The gate contact CB3 may be in contact with the upper surface of the second gate electrode G2. The gate contact CB3 may overlap with the active cut 360 in the first horizontal direction DR1. For example, the upper surface of each of the contact via V31 and the gate contact CB3 may be formed on the same plane as the upper surface of the active cut 360. Each of the contact via V31 and the gate contact CB3 may include a conductive material.

Hereinafter, a fabrication method of a semiconductor device according to some example embodiments will be described with reference to FIGS. 36 to 43. The description will focus on the differences from the fabrication method of the semiconductor device shown in FIGS. 5 to 32.

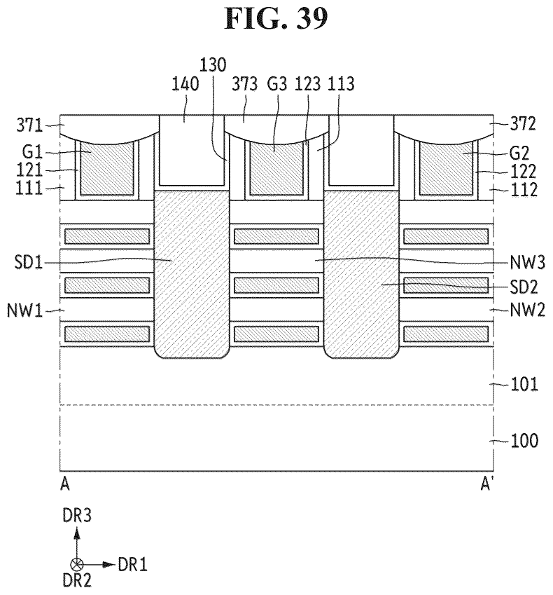

FIGS. 39 to 43 are intermediate stage diagrams for explaining a fabrication method of a semiconductor device according to some example embodiments.

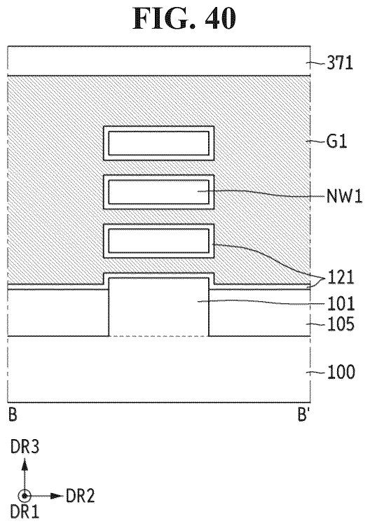

Referring to FIGS. 39 and 40, after performing the fabrication process shown in FIGS. 5 to 15, a first gate insulating layer 121, a first gate electrode G1, and a first capping pattern 371 may be formed sequentially inside the first gate trench GT1 (see FIG. 14). The first gate electrode G1 may surround the first plurality of nanosheets NW1. A second gate insulating layer 122, a second gate electrode G2, and a second capping pattern 372 may be formed sequentially inside the second gate trench GT2 (see FIG. 14). The second gate electrode G2 may surround the second plurality of nanosheets NW2. A third gate insulating layer 123, a third gate electrode G3, and a third capping pattern 373 may be formed sequentially inside the third gate trench GT3 (see FIG. 14). The third gate electrode G3 may surround the third plurality of nanosheets NW3.

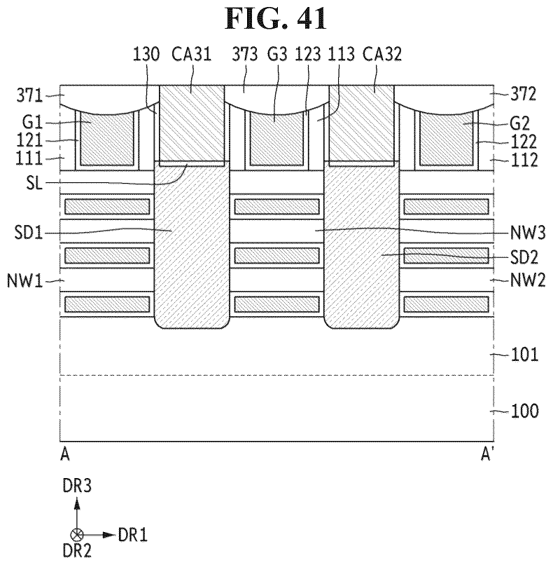

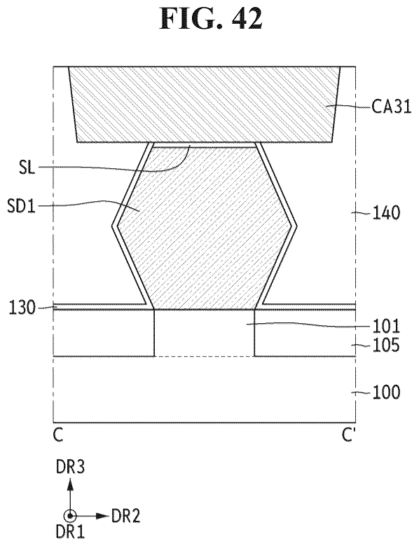

Referring to FIGS. 41 and 42, a first source/drain contact CA31 may be formed on the upper surface of the first source/drain region SD1 inside the first interlayer insulating layer 140. Further, the second source/drain contact CA32 may be formed on the upper surface of the second source/drain region SD2 inside the first interlayer insulating layer 140. For example, the upper surface of each of the first and second source/drain contacts CA31, CA32 may be formed on the same plane as the upper surface of each of the first interlayer insulating layer 140, and the first to third capping patterns 371, 372, 373. Additionally, a silicide layer SL may be formed along the interface between the first source/drain region SD1 and the first source/drain contact CA31. The silicide layer SL may be formed along the interface between the second source/drain region SD2 and the second source/drain contact CA32.

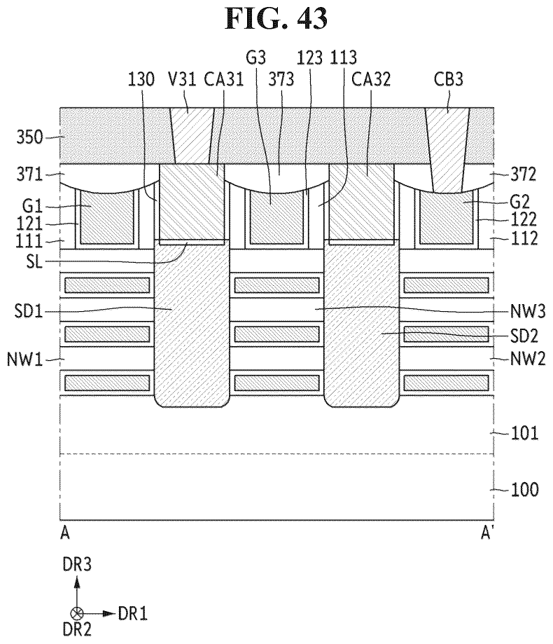

Referring to FIG. 43, the second interlayer insulating layer 350 may be formed on the upper surface of each of the first interlayer insulating layer 140, the first and second source/drain contacts CA31, CA32, and the first to third capping patterns 371, 372, 373. A contact via V31 may be formed to penetrate the second interlayer insulating layer 350 in the vertical direction DR3 and connect to the first source/drain contact CA31. Further, the gate contact CB3 may be formed to penetrate the second interlayer insulating layer 350 and the second capping pattern 372 in the vertical direction DR3 and connect to the second gate electrode G2.

Referring to FIGS. 36 to 38, an active cut 360 may be formed to penetrate the second interlayer insulating layer 350, the third capping pattern 373, the third gate electrode G3, the third gate insulating layer 123, the third plurality of nanosheets NW3, and the active pattern 101 in the vertical direction DR3. The active cut 360 may extend in the vertical direction DR3 into the substrate 100. The active cut 360 may extend in the second horizontal direction DR2. For example, the upper surface of the active cut 360 may be formed on the same plane as the upper surface of each of the contact via V31, the gate contact CB3, and the second interlayer insulating layer 350. Through such a fabrication process, the semiconductor device shown in FIGS. 36 to 38 may be fabricated.

Hereinafter, with reference to FIGS. 36 to 38 and FIG. 44, the fabrication method of a semiconductor device according to some example embodiments will be described. The description will focus on the differences from the fabrication method of the semiconductor device shown in FIGS. 5 to 15 and FIGS. 39 to 43.

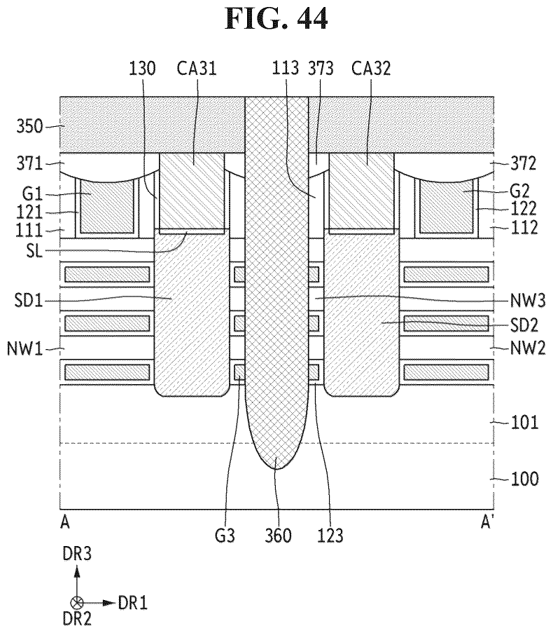

FIG. 44 is an intermediate stage diagram for explaining the fabrication method of a semiconductor device according to some example embodiments.

Referring to FIG. 44, after performing the fabrication process shown in FIGS. 5 to 15 and FIGS. 39 to 42, a second interlayer insulating layer 350 may be formed on the upper surface of each of the first interlayer insulating layer 140, the first and second source/drain contacts CA31, CA32, and the first to third capping patterns 371, 372, 373. The active cut 360 may be formed to penetrate the second interlayer insulating layer 350, the third capping pattern 373, the third gate electrode G3, the third gate insulating layer 123, the third plurality of nanosheets NW3, and the active pattern 101 in the vertical direction DR3. The active cut 360 may extend in the vertical direction DR3 into the substrate 100. The active cut 360 may extend in the second horizontal direction DR2. For example, the upper surface of the active cut 360 may be formed on the same plane as the upper surface of the second interlayer insulating layer 350.

Referring to FIGS. 36 to 38, a contact via V31 may be formed to penetrate the second interlayer insulating layer 350 in the vertical direction DR3 and connect to the first source/drain contact CA31. Further, a gate contact CB3 may be formed to penetrate the second interlayer insulating layer 350 and the second capping pattern 372 in the vertical direction DR3 and connect to the second gate electrode G2. Through such a fabrication process, the semiconductor device shown in FIGS. 36 to 38 may be fabricated.

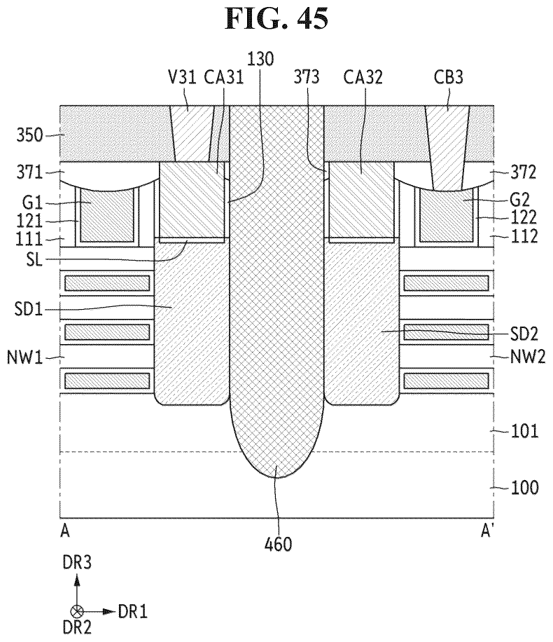

Hereinafter, with reference to FIG. 45, a semiconductor device according to some example embodiments will be described. The description will focus on the differences from the semiconductor device shown in FIGS. 36 to 38.

FIG. 45 is a cross-sectional view for explaining a semiconductor device according to some example embodiments.

Referring to FIG. 45, in a semiconductor device according to some example embodiments, both sidewalls of the active cut 460 in the first horizontal direction DR1 may be in contact with the first and second source/drain regions SD1, SD2. For example, both sidewalls of the active cut 460 in the first horizontal direction DR1 may be in contact with each of the etching stop layer 130 and the third capping pattern 373.

While aspects of example embodiments have been particularly shown and described, it will be understood that various changes in form and details may be made therein without departing from the spirit and scope of the following claims.

What is claimed is:

1. A semiconductor device comprising:
a substrate;
an active pattern extending along a first horizontal direction on an upper surface of the substrate;
a first plurality of nanosheets spaced apart from each other along a vertical direction on the active pattern;
a first gate electrode extending along a second horizontal direction different from the first horizontal direction on the active pattern, wherein the first gate electrode surrounds the first plurality of nanosheets;
an active cut spaced apart from the first gate electrode in the first horizontal direction, wherein a bottom surface of the active cut is provided between a bottom surface of the substrate and a bottom surface of the first gate electrode;
a source/drain region provided between the first gate electrode and the active cut on the active pattern; and
a source/drain contact provided on an upper surface of the source/drain region, wherein the source/drain contact is electrically connected to the source/drain region, and an uppermost surface of the source/drain contact is provided between the bottom surface of the substrate and an upper surface of the active cut.

2. The semiconductor device of claim 1, further comprising a contact via in contact with an upper surface of the source/drain contact, wherein the contact via is electrically connected to the source/drain contact, and the contact via overlaps with the active cut along the first horizontal direction.

3. The semiconductor device of claim 2, wherein the upper surface of the active cut is coplanar with an upper surface of the contact via.

4. The semiconductor device of claim 1, further comprising:
a second plurality of nanosheets spaced apart from each other along the vertical direction on the active pattern, and spaced apart from the active cut along the first horizontal direction;
a second gate electrode extending along the second horizontal direction on the active pattern, wherein the second gate electrode is spaced apart from the active cut along the first horizontal direction, and the second gate electrode surrounds the second plurality of nanosheets; and
a gate contact in contact with an upper surface of the second gate electrode, wherein the gate contact is electrically connected to the second gate electrode, and the gate contact overlaps with the active cut along the first horizontal direction.

5. The semiconductor device of claim 4, wherein the upper surface of the active cut is coplanar with an upper surface of the gate contact.

6. The semiconductor device of claim 1, further comprising:
a first interlayer insulating layer surrounding sidewalls of the source/drain region along the second horizontal direction; and
a second interlayer insulating layer provided on an upper surface of the first interlayer insulating layer, wherein the second interlayer insulating layer is in contact with sidewalls of the active cut along the first horizontal direction, and an upper surface of the second interlayer insulating layer is coplanar with the upper surface of the active cut.

7. The semiconductor device of claim 6, wherein the second interlayer insulating layer is in contact with an upper surface of the first gate electrode.

8. The semiconductor device of claim 6, wherein a bottom surface of the second interlayer insulating layer is provided between the bottom surface of the substrate and the uppermost surface of the source/drain contact.

9. The semiconductor device of claim 1, wherein the source/drain contact comprises:
a first portion provided on the upper surface of the source/drain region; and
a second portion protruding from an upper surface of the first portion along the vertical direction, and
wherein a width along the second horizontal direction of the upper surface of the first portion of the source/drain contact is greater than a width along the second horizontal direction of a bottom surface of the second portion of the source/drain contact.

10. The semiconductor device of claim 1, further comprising:
a third plurality of nanosheets stacked and spaced apart from each other along the vertical direction on the active pattern, and spaced apart from the first plurality of nanosheets along the first horizontal direction; and
a third gate electrode extending along the second horizontal direction on the active pattern, wherein the third gate electrode is spaced apart from the first gate electrode along the first horizontal direction, and the third gate electrode surrounds the third plurality of nanosheets,
wherein each of the third gate electrode and the third plurality of nanosheets is in contact with sidewalls of the active cut along the first horizontal direction.

11. The semiconductor device of claim 1, wherein sidewalls of the active cut along the first horizontal direction are in contact with the source/drain region.

12. The semiconductor device of claim 1, further comprising a capping pattern extending along the second horizontal direction on an upper surface of the first gate electrode, wherein the capping pattern is in contact with the upper surface of the first gate electrode, an upper surface of the capping pattern is provided between the bottom surface of the substrate and the upper surface of the active cut, wherein the upper surface of the capping pattern is coplanar with an upper surface of the source/drain contact.

13. A semiconductor device comprising:
a substrate;
an active pattern extending along a first horizontal direction on an upper surface of the substrate;
a first gate electrode extending along a second horizontal direction different from the first horizontal direction on the active pattern;
a second gate electrode extending along the second horizontal direction on the active pattern, wherein the second gate electrode is spaced apart from the first gate electrode along the first horizontal direction;
an active cut extending along the second horizontal direction between the first gate electrode and the second gate electrode, wherein the active cut is spaced apart from each of the first gate electrode and the second gate electrode along the first horizontal direction;
a first source/drain region provided between the first gate electrode and the active cut on the active pattern;
a first source/drain contact provided on an upper surface of the first source/drain region, wherein the first source/drain contact is electrically connected to the first source/drain region; and
a contact via in contact with an upper surface of the first source/drain contact, wherein the contact via is electrically connected to the first source/drain contact, and an upper surface of the contact via is coplanar with an upper surface of the active cut.

14. The semiconductor device of claim 13, wherein an uppermost surface of the first source/drain contact is between a bottom surface of the substrate and the upper surface of the active cut.

15. The semiconductor device of claim 13, further comprising a gate spacer provided on both sidewalls of the active cut along the first horizontal direction, wherein an uppermost surface of the gate spacer is provided between a bottom surface of the substrate and the upper surface of the active cut.

16. The semiconductor device of claim 13, further comprising:
a second source/drain region provided between the active cut and the second gate electrode on the active pattern; and
a second source/drain contact provided on an upper surface of the second source/drain region, wherein the second source/drain contact is electrically connected to the second source/drain region,
wherein, on the active pattern, an upper surface of the second source/drain contact is provided between a bottom surface of the substrate and the upper surface of the first source/drain contact.

17. The semiconductor device of claim 13, further comprising a gate contact in contact with an upper surface of the second gate electrode, wherein the gate contact is electrically connected to the second gate electrode, and an upper surface of the gate contact is coplanar with the upper surface of the active cut.

18. The semiconductor device of claim 17, wherein a bottom surface of the contact via is coplanar with a bottom surface of the gate contact.

19. The semiconductor device of claim 13, wherein sidewalls of the active cut along the first horizontal direction are in contact with the contact via.

20. A semiconductor device comprising:
a substrate;
an active pattern extending along a first horizontal direction on an upper surface of the substrate;
a first plurality of nanosheets spaced apart from each other along a vertical direction on the active pattern;
a second plurality of nanosheets spaced apart from each other along the vertical direction on the active pattern, and spaced apart from the first plurality of nanosheets along the first horizontal direction;
a third plurality of nanosheets spaced apart from each other along the vertical direction on the active pattern, wherein the third plurality of nanosheets are provided between the first and second plurality of nanosheets, and the third plurality of nanosheets are spaced apart from each of the first and second plurality of nanosheets along the first horizontal direction;
a first gate electrode extending along a second horizontal direction different from the first horizontal direction on the active pattern, wherein the first gate electrode surrounds the first plurality of nanosheets;
a second gate electrode extending along the second horizontal direction on the active pattern, wherein the second gate electrode is spaced apart from the first gate electrode along the first horizontal direction, and the second gate electrode surrounds the second plurality of nanosheets;
a third gate electrode extending along the second horizontal direction on the active pattern, wherein the third gate electrode is provided between the first and second gate electrodes, the third gate electrode is spaced apart from each of the first and second gate electrodes along the first horizontal direction, and the third gate electrode surrounds the third plurality of nanosheets;
an active cut extending along the second horizontal direction between the first and second gate electrodes, wherein the active cut penetrates the third plurality of nanosheets and the third gate electrode along the vertical direction;
a source/drain region provided between the first gate electrode and the active cut on the active pattern;
a source/drain contact provided on an upper surface of the source/drain region, wherein the source/drain contact is electrically connected to the source/drain region, and an uppermost surface of the source/drain contact is provided between a bottom surface of the substrate and an upper surface of the active cut;
a contact via in contact with an upper surface of the source/drain contact, wherein the contact via is electrically connected to the source/drain contact, and an upper surface of the contact via is coplanar with the upper surface of the active cut; and
a gate contact in contact with an upper surface of the second gate electrode, wherein the gate contact is electrically connected to the second gate electrode, and an upper surface of the gate contact is coplanar with the upper surface of the active cut.
